(19) United States
(12) Patent Application Publication
(10) Pub. No.: US 2006/0202865 A1
(43) Pub. Date: Sep. 14, 2006

(54) Text entry coding system and handheld computing device

(76) Inventor: Mitchell Van Nguyen, Westminster, CA (US)

Correspondence Address: ROY A. EKSTRAND, STE 150, 3158 REDHILL AVE., COSTA MESA, CA, 92626, US

(21) Appl. No.: 11/072,135

(22) Filed: Mar. 4, 2005

(51) Int. Cl. H03M 11/00; H03K 17/94

(52) U.S. Cl. 341/22; 341/35

(57) ABSTRACT

A keystroke chording system operative within a computing system such as a PDA or the like employs the multi-position joystick control or its equivalent together with a plurality of discreet input buttons to provide text entry. The system utilizes highly effective chording techniques to allow the user to employ additional shift keys positioned upon the PDA computing unit to increase the available combinations of chorded keystrokes produced by joystick and action button actuation of the unit. The use of additional shift keys facilitates a highly effective and efficient chorded keystroke system.

### FIELD OF THE INVENTION

This invention relates generally to handheld computing devices and particularly to text entry or typing systems utilized therewith.

### BACKGROUND OF THE INVENTION

With the exploding use of computers, the existing standard keyboard arrangement previously used in typewriter devices was largely adopted as the standard for computer keyboard input devices. While numerous keys were added to meet the additional needs of inputting additional instruction and information to computers which were not generally required by typewriters of the time, the standard arrangement of the twenty six alphabet keys then in use in typewriters remains virtually unchanged in computer keyboards. Also, many associated keys such as keys utilized in punctuation are also often arranged in a typewriter-like key arrangement in modem computer keyboards.

Through the years, various alternatives to the standard alphabet key arrangement have been proposed. However, the well established typewriter standard has proven difficult to replace. As a result, the now standard basic key arrangement utilized in computer keyboards forms the fundamental primary and basic text input device for users. In later years, a further input device generally referred to as a mouse was added to the keyboard for computer input use. Such mouse input devices are most typically utilized in combination with so-called menu-driven operating systems and the like. While the use of mouse devices has greatly improved the users friendly character of computer systems, the basic data and text input device for computers in wide use remains the standard keyboard.

As computers evolved, more powerful processors and greater memory capacity became available. This in turn resulted in the practical use of far more sizable and complex operating systems and productivity software. In a further development resulting from computer device evolution and improvement, so-called portable or “laptop” computers became available. For the most part, such portable or laptop computers included many changes and advantages to improve their compact fabrication and portability. However, for the most part, such devices have largely retained the now standard alphabet character key arrangement utilized in other computer keyboards and typewriter devices.

In a still further development stage of the continuing computer evolution, even smaller devices sized to be generally described as handheld computers have been provided. Often called personal data assistants or PDA such handheld computer devices have proven to be excellent for general use, schedule maintenance and other activities. However, tasks such as text entry have remained a problem. In the typical PDA type device, a small generally thin flat housing having a more or less rectangular height or width aspect ratio is used to support a processor and memory. The PDA typically includes a touch screen display device together with a stylus instrument for interacting with the touch screen display. Other input devices typically include a multi-position joystick control together with a plurality of depressible buttons positioned on the various edges and surfaces of the device.

Practitioners in the art quickly recognized that despite the many uses for such PDA-type devices which could be readily accomplished, the activity of text entry proved difficult and some what cumbersome. Faced with the need to provide text entry, practitioners in the art have provided several systems which have included keyboard image systems, stylus write-in systems, miniature keyboards and button input systems using chorded processing.

The use of keyboard images and stylus involves displaying a standard alphabet keyboard similar to a typewriter upon the display. Text is inputted as the user touches the stylus to each key image to input the text or data. In essence, this process proceeds much like a typing process in which a single finger is employed. Letter keys are “touched” on a one by one basis.

The stylus writing input system utilizes a software system in which the user is able to “write” upon the touch screen display in a typical hand lettering or handwriting process. Once the user has written a certain amount of information on the screen, the specialized software within the device is able to decipher the handwriting or hand lettering and produce typed text corresponding to the written or lettered material.

The button input and chorded button systems employ conventional chording to vary the alphabet characters and other text entry key meanings assigned to the limited number of buttons upon the device. Chording is a relatively well known process in which a given group of buttons or keys may be accorded different significance as a function of the chording key. Perhaps one of the most well known examples of chording is found in the use of the shift key in a conventional keyboard to alter the alphabet keys between lower case and upper case assignment.

In a similar manner, chording systems have been utilized in attempting to improve text entry and data entry operations with PDAs and other similar handheld computing units. One such prior art device is set forth in U.S. Pat. No. 5,515,305 issued to Register et al. which sets forth a PDA HAVING CHORD KEYBOARD INPUT DEVICE AND METHOD OF PROVIDING DATA THERETO in which a handheld PDA unit includes a chassis having first and second noncoplanar surfaces thereon supports computer processing circuitry therein. The unit further includes a visual display located on one of the surfaces which is operatively coupled to the computer processing circuitry. A plurality of keys located on both the first and second surfaces are operatively coupled to the computer processing circuitry. The plurality of keys cooperate to form a chord keyboard thereby allowing multiple ones of the keys to be concurrently depressed to form a chord. The computer processing circuitry within the unit interprets the chord or combination of keystrokes as a single keystroke input.

While the use of keyboard chording has raised the possibility for providing effective text entry and data entry into such small units such as PDAs and the like, their present implementations require further improvement. Thus, the promise of high efficiency and high speed text entry and data entry in PDAs or the like may be better realized using the present invention system.

### SUMMARY OF THE INVENTION

Accordingly, it is a general object of the present invention to provide an improved handheld computing device. It is a more particular object of the present invention to provide a system for text entry and data entry for handheld computing devices which is extremely effective and efficient.

In accordance with the present invention, there is provided a keystroke chording system operative within a computing system such as a PDA or the like which employs the multi-position joystick control or its equivalent together with a plurality of discreet input buttons to provide text entry. The system may further employ additional shift keys positioned upon the PDA computing unit to increase the available keystroke signals produced by joystick and action button actuation of the unit. The use of additional shift keys facilitates a highly effective and efficient chorded keystroke system and provide a means for expanding the working character set.

In accordance with the present invention, there is also provided a keystroke chording system operative within a computing system comprising: a multi-position control; a plurality of discreet input buttons and means operative within the computing system for inputting data using said multi-position control and said input buttons wherein each combination of joystick position input and input button input produces a character input to the computing system.

### BRIEF DESCRIPTION OF THE DRAWINGS

The features of the present invention, which are believed to be novel, are set forth with particularity in the appended claims. The invention, together with further objects and advantages thereof, may best be understood by reference to the following description taken in conjunction with the accompanying drawings, in the several figures of which like reference numerals identify like elements and in which:

FIG. 1 sets forth a front view of an illustrative PDA computer device constructed in accordance with conventional fabrication techniques which further houses the present invention keystroke chording system;

FIG. 2 sets forth a front view of the device of FIG. 1 in a simplified view to more clearly show the apparatus used in the present invention system operation;

FIG. 3 sets forth a keystroke diagram of the present invention system in which the shift state of zero is employed;

FIG. 4 sets forth the keystroke diagram of the present invention system in which the shift state of one or one locked is employed;

FIG. 5 sets forth the keystroke diagram of the present invention system in which the shift state of two or two locked is employed;

FIG. 6 sets forth the keystroke diagram of the present invention system in which the shift state of three or three locked is employed;

FIG. 7 sets forth a diagram of the primary action and operation of the present invention system;

FIG. 8 sets forth an overview flow diagram of the present invention system;

FIG. 9 sets forth an overview flow diagram of an alternate embodiment of the present invention system;

FIG. 10 sets forth an overview flow diagram of a further alternate embodiment of the present invention system;

FIG. 11 sets forth a flow diagram of the present invention system;

FIG. 12 sets forth a flow diagram of the present invention system operative in response to actuation of action key 14;

FIG. 13 sets forth a flow diagram of the present invention system operative in response to actuation of action key 15;

FIG. 14 sets forth a flow diagram of the present invention system operative in response to the actuation of action key 16;

FIG. 15 sets forth a flow diagram of the present invention system operative in response to actuation of action key 17;

FIG. 16 sets forth a flow diagram of the present invention system operative in response to actuation of shift key 23;

FIG. 17 sets forth a flow diagram of the present invention system operative in response to actuation of shift key 18;

FIG. 18 sets forth a flow diagram of the operation of the present invention system operative in response to actuation of shift key 19;

FIG. 19 sets forth a flow diagram of the execute 1 operation of the present invention system;

FIGS. 20, 21, 22, 23 and 28 set forth alternate recesses for joysticks for use in the present invention system; and

FIGS. 24, 25, 26 and 27 set forth alternate eight-direction joystick alternative button embodiments for use in the present invention system.

### DESCRIPTION OF THE PREFERRED EMBODIMENTS OF THE INVENTION

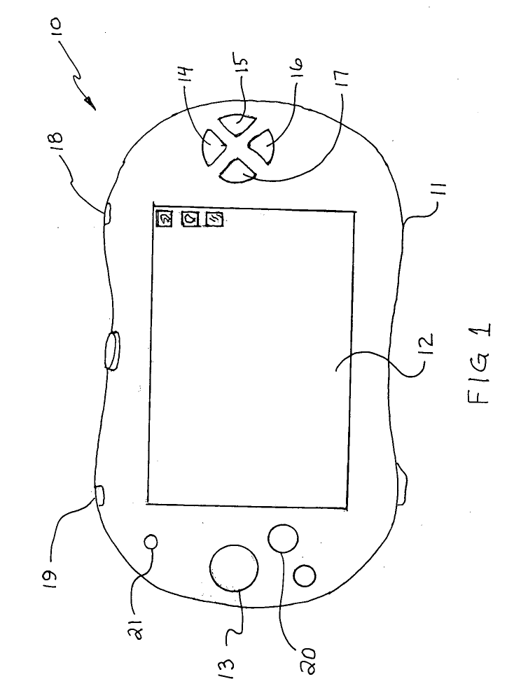

FIG. 1 sets forth a PDA device generally referenced by numeral 10 which is apart from the present invention text entry coding system installed therein, fabricated in accordance with conventional fabrication techniques. In the illustrative example set forth in FIG. 1, PDA 10 is a Zodiac 1 device manufactured and distributed by Tapwave. Development tools, which may include Code Warrior Development Studio for Palm OS version 9.3, PiIRC designer for Palm OS version 2.1.3.0. Palm OS5(68K) R3 and Tapwave 1.1 SDK can be used in developing the required code for the embodiments of the system software set forth below. It will be apparent to those skilled in the art while the Tapwave device set forth in FIG. 1 provides a suitable operating environment for the present invention text entry coding system, other devices having other software systems may be utilized without departing from the spirit and scope of the present invention. Thus, the embodiment set forth in FIG. 1, utilizing Tapwave device 10 should be understood to be merely illustrative of a variety of similar devices.

More specifically, PDA 10 includes a housing 11 supporting a touch screen display 12. Housing 11 further supports an eight position joystick control 13 having a push button center switch actuated by knob 23 together with a plurality of action buttons 14, 15, 16 and 17. It will be apparent to those skilled in the art that a variety of multiple input devices such as an analog controller, game pad or D-pad may be used in place of joystick control 13 without departing from the spirit and scope of the present invention. Device 10 further includes a left trigger 19 and a right trigger 18 supported by housing 11 along the upper edge thereof. A function button 20 is also supported upon the front surface of housing 11. A power button 21 is operative to turn device 10 on and off. While not seen in FIG. 1, it will be understood that device 10 includes a computing system circuit and memory apparatus constructed in accordance with conventional fabrication techniques which is operatively coupled to the various controls and inputs as well as display 12.

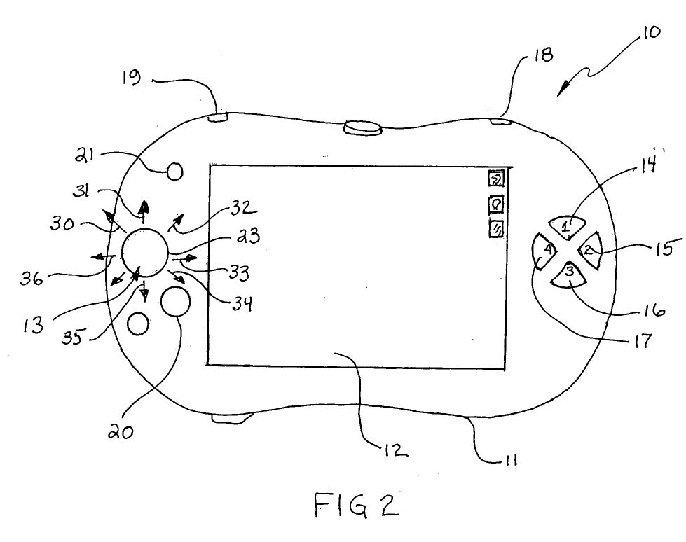

FIG. 2 sets forth a simplified front view of PDA 10 shown in FIG. 1. The purpose of simplifying the depiction of FIG. 2 is to omit many controls and button inputs which are not active in carrying forward the present invention text entry coding system. Thus, as mentioned above, PDA 10 includes a generally planar housing 11 having a touch screen display 12 supported thereon. As is also described above, PDA 10 includes, as a minimum an eight direction joystick control 13 together with a quartet of action keys 14, 15, 16 and 17. Also supported upon housing 11 is a shift key 18 and a shift key 19 on the upper edges of housing 11. An additional button 20 also supported by housing 11 is utilized to provide the “button 0” input in the present invention text entry coding. In addition, joystick 13 is constructed in accordance with conventional fabrication techniques and thus includes a depressible button input for joystick knob 23.

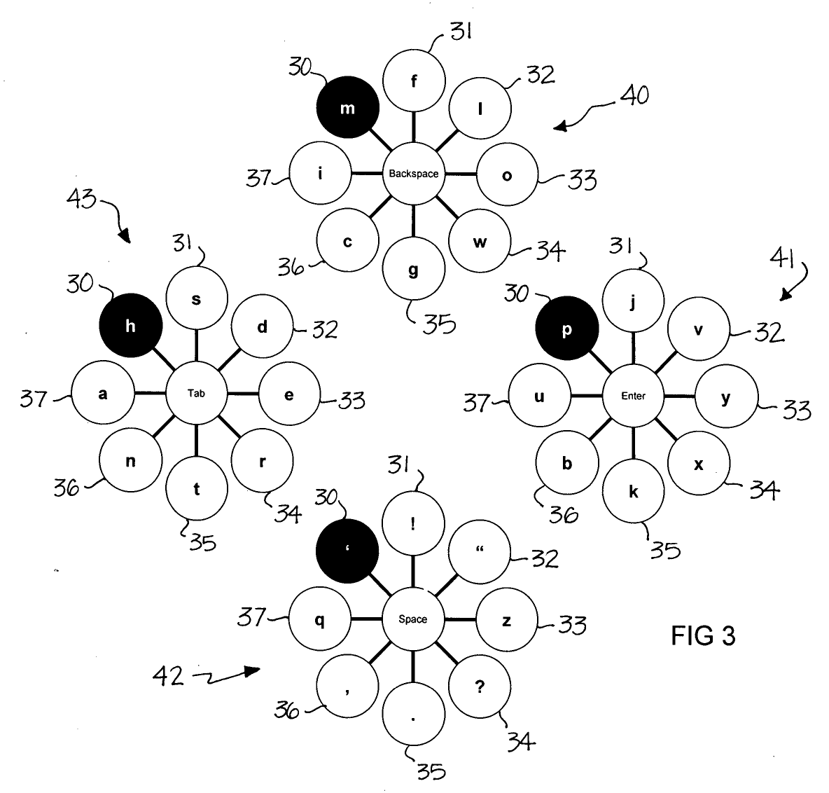

The keystroke coding utilized in the present invention text entry coding system is set forth below in FIGS. 3, 4, 5 and 6 in which the various keystroke coding combinations utilized and resulting key definitions are set forth. Suffice it to note here that the user holds PDA 10 in both hands preferably such that action keys 14 through 17 are manipulatable with the users right thumb while shift key button 18 is manipulated by the user's right hand index finger. Similarly, as the user grasps PDA 10 with both hands, the user's left thumb is utilized in operating joystick 13 as well as the depressible switch responsive to pressing knob 23 downwardly and pressing additional button 20. Further, the user's left hand index finger is utilized in actuating shift key button 19. In this manner, the user is able to access all buttons necessary for keystroke chording and shift state selection without significant movement of the user's hands in holding PDA 10. For example, the user is able to use the user's left hand to manipulate joystick 13 while either depressing shift key button 19 or knob 23. By further example, the user is simultaneously able to use the user's right hand to manipulate action keys 14 through 17 while also manipulating shift key button 18.

Thus, while holding PDA 10 in both right and left hands, the user is able to select a desired shift state (button 18, 19 or 23) which selects a desired keyboard of characters (see FIGS. 3, 4, 5 and 6) and thereafter chord a selected one of action keys 14, 15, 16 or 17 together with a selected joystick position of joystick controller 13 to output a selected character to display 12 and the PDA's text input. It should be noted that the terms “joystick position” and “joystick direction” may be used interchangeably when describing the operation of joystick controller 13.

Each of shift key buttons 18, 19 and 23 operates to select between a set of three shift states. Shift key button 23 selects between shift state 0, shift state 1 and shift state 1 locked in repetitive sequence incremented each time shift key button 23 is pressed. Thus, shift state is initially 0 and is incremented to shift state 1 when shift key button 23 is initially pressed one time. Once the character is outputted, joystick 13 and a selected action key chording), the shift state reverts to shift state 0. If shift key button 23 is pressed twice, a shift state of 1 locked is set. Unlike shift state 1, shift state 1 locked does not revert to shift state 0 when a character is outputted. Rather, shift state 1 locked continues through multiple character outputs until shift key knob 23 is again pressed returning the system to shift state 0 or to another shift state when another shift state button is pressed. Further, each shift state button is able to directly establish a given shift state. It is not necessary to “sequence through” shift states.

In a similar manner, shift key button 18 operates to repetitively increment from shift state 0 to shift state 2 to shift state 2 locked and return to shift state 0. Finally, shift key button 19 operates to repetitively increment from shift state 0 to shift state 3 to shift state 3 locked and return to shift state 0 each time shift key button 19 is pressed. Thus, the user is able to select a desired character by setting a shift state and chording a selected action key and a joystick position. For example, with the default or initial shift state 0 set, the keyboard or character set shown in FIG. 3 is established. Once shift state 0 is set, the available characters (FIG. 3) enables the user to input all lower case alpha characters, and punctuation marks by the simple combination of joystick 13 position together with the appropriate chording of a selected one of action keys 14 through 17. By way of illustration, and with temporary referenced to FIG. 3, it will be noted that moving joystick 13 upwardly in the direction indicated by arrow 30 while chording (simultaneously pressing) action key 14 results in a lower case “m” character output from the computing system to provide a text input. Similarly, with joystick 13 moved to the position indicated by arrow 30 while pressing action key 15 results in inputting a lower case “p”. With joystick 13 again moved to the position indicated by arrow 30 and action key 16 pressed, an apostrophe is inputted. Finally, with joystick 13 again moved to the position indicated by arrow 30 and then pressing action key 17, a lower case “h” is inputted. In a similar fashion, each of the positions of joystick 13 results in a character output which is determined by which selected one of keys 14 through 17 is simultaneously pressed (that is to say chorded). In this manner, the eight directions of movement of joystick 13 together with the four action keys 14 through 17 result in the capability of outputting thirty two characters or punctuation marks or codes.

The text entry coding of the present invention system is further operative when the user in addition to moving joystick knob 23 and one of action keys 14 through 17 also depresses either shift state buttons 18, 19 or 23 to enter a change of shift state. It should be noted that while the embodiments of the present invention system set forth herein utilize “buttons” to implement shift state changes, other input devices, such as tilt switches, momentum switches, display icons on the screen and so on. As mentioned above, shift state is changed each time a shift state button is depressed. It should also be noted that a greater number of shift states may be provided depending on the number of codes needed. Also, fewer shift states may be used if fewer characters (i.e. only lower case) are used. In addition, it will be further apparent that a different number of shift state button may be used without departing from the spirit and scope of the present invention. For example, a single shift state button could be used to sequence through a larger number of shift states (eg. 0, 1, 1 locked, 2, 2 locked, 3, 3 locked and back to 0).

In addition to the above-described chording system for text entry, the present invention system is operative in response to action keys 14 through 17 together with button 20 to provide further data input. In particular, pressing action key 14 alone in the absence of other inputs produces a “backspace” input. Similarly, pressing action key 15 in the absence of other key inputs creates a “enter” input. In a similar fashion, pressing action key 16 in the absence of other key inputs results in a “space” input while pressing action key 17 in the absence of other inputs produces a “tab” input. The flexibility of the present invention system is further increased by adding an input from button 20 while action keys 14 through 17 are pressed. Thus, with button 20 pressed, pressing action key 14 produces an up movement of the cursor while pressing action key 15 moves the cursor to the right. Similarly, with button 20 pressed, pressing action key 16 moves the cursor down while pressing action key 17 moves the cursor to the left. This is equivalent to up, down, left, right arrow buttons on a keyboard.

In this fashion, the present invention text coding system is operative in response to multiple inputs while the user is able to hold PDA 10 in both hands while avoiding the need to make significant hand movements. The result is extremely efficient, high-speed text and data entry once the user becomes accustom to the chording system. This allows touch typing meaning that the user doesn't need to look at the data entry system while entering data.

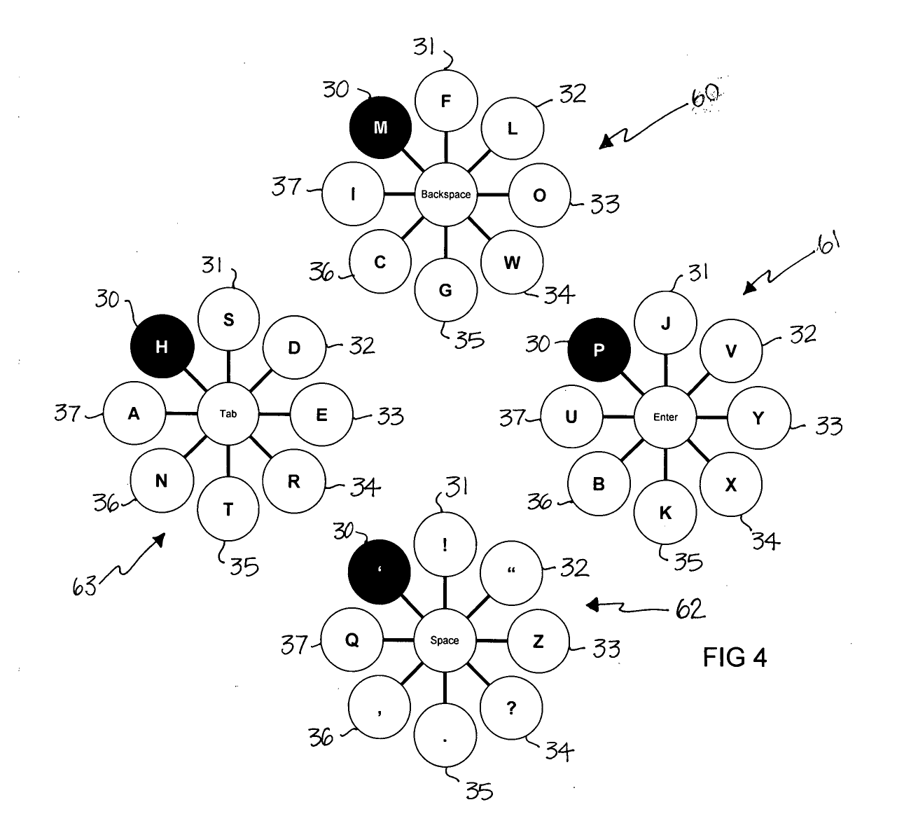

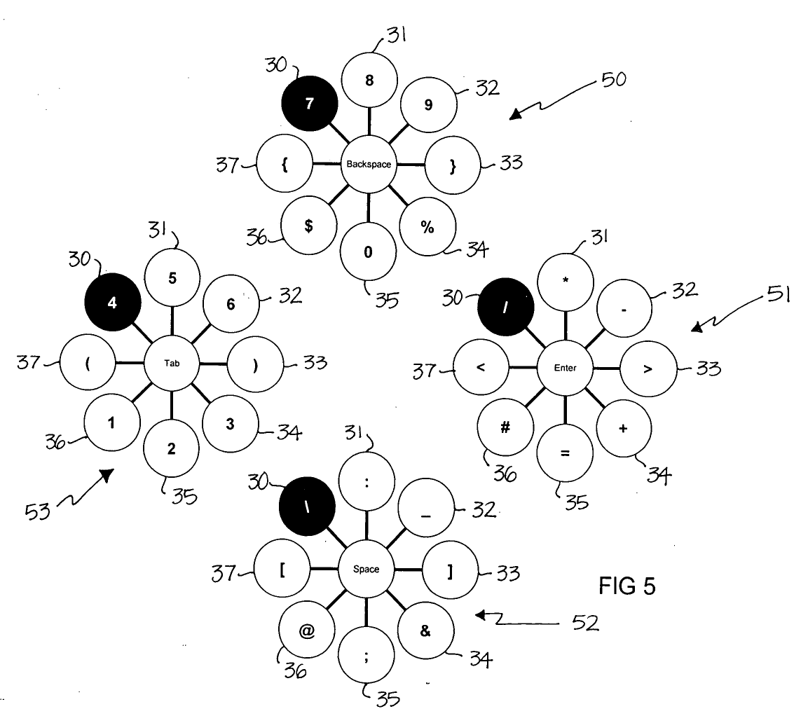

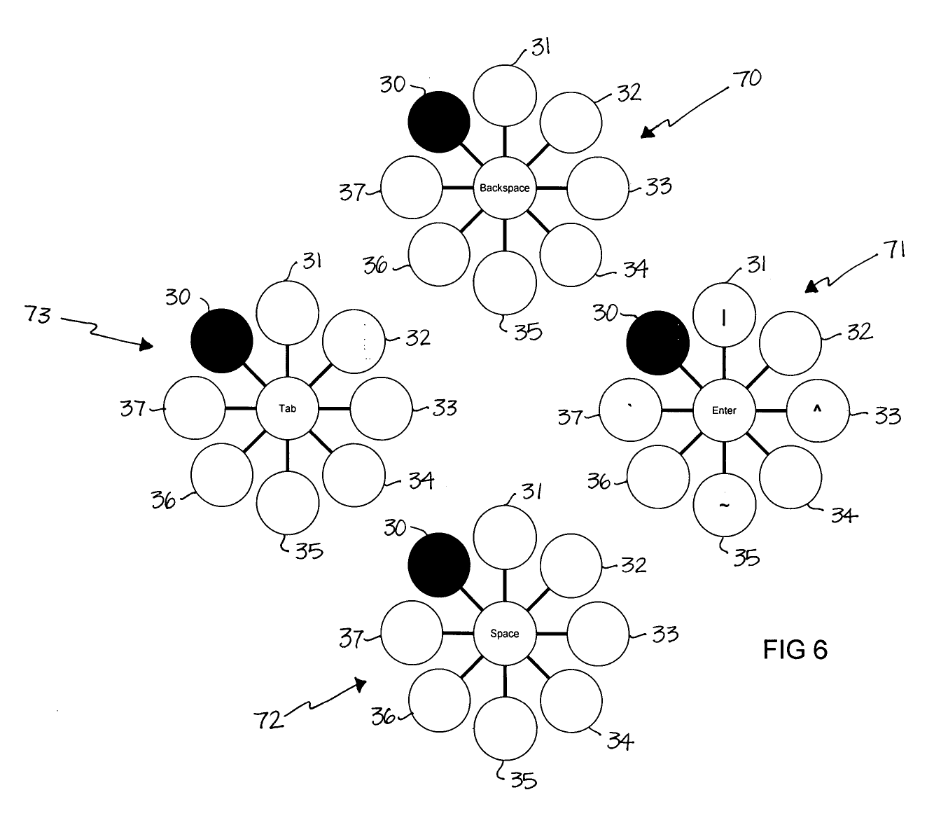

By way of overview, FIGS. 3, 4, 5 and 6 set forth respective keyboard diagrams resulting from setting shift state 0, 1, 2 or 3 respectively. Each of FIGS. 3, 4, 5 and 6 shows the characters available in each shift state by chording of joystick 13 with action keys 14, 15, 16 and 17. Each of the characters group diagrams utilizes eight circles arranged in correspondence to the eight positions of joystick 13 set forth above in FIG. 2. The character group diagrams in FIGS. 3, 4, 5 and 6 are identical in their depictions of joystick movement directions with the only differences between character groups being found in the chorded action keys. Thus, FIG. 3 sets forth the chording of joystick 13 together with action keys 14 through 17 resulting during shift state zero which is the shift state resulting from shift state variable being zero. Similarly, FIG. 4 shows the character groups available by chording eight positions of joystick 13 movement together with action keys 14 through 17 while in shift state one or one locked (shift key 23 having been depressed causing the shift state to increment from 0 to 1 or twice to one locked). Similarly, FIG. 5 sets forth the character groups available by chording the eight positions of joystick 13 and action keys 14 through 17 while shift state 2 or 2 locked is set by pressing shift key button 18 once or twice respectively. Finally, FIG. 6 sets forth the character groups resulting in shift state 3 or three locked (shift key 19 having been depressed once or twice respectively).

It will be recognized that the use of four action keys to access four character groups within the keyboards show in FIGS. 3, 4, 5 and 6 is selected by way of example, Other number of action keys and corresponding number of character groups (such as five) may be used without departing from the present invention.

More specifically, FIG. 3 sets forth character groups 40 through 43 corresponding to action keys 14 through 17 while the system is set to shift state 0. Character group 40 corresponds to the eight directions of joystick 13 and the characters resulting when action key 14 is pressed. Thus, joystick directions 30, 31, 32, 33, 34, 35, 36, and 37 result in outputting lower case characters m, f, l, o, w, g, c, i, when action key 14 is pressed. Similarly, as is set forth in character group 41 which corresponds to action key 15 being pressed, joystick directions 30 through 37 result in lower case outputs p, j, v, y, x, k, b, u. Similarly, as is set forth in character group 42 which corresponds to action key 16 being pressed, joystick directions 30 through 37 result in character outputs of apostrophe, exclamation mark, quote, lower case z, question mark, period, comma, and lower case q. Finally, FIG. 3 sets forth character group 43 corresponding to directional movements 30 through 37 of joystick 13 while action key 17 is pressed. With action key 17 pressed, joystick movements in directions 30 through 37 result in character inputs of lower case h, s, d, e, r, t, n and a.

FIG. 4 sets forth the corresponding character group diagrams for shift state 1 and 1 locked. Thus, diagram 60 sets forth the character inputs for joystick directions 30 through 37 with action key 14 pressed while diagram 61 sets forth character inputs for joystick positions 30 through 37 with action key 15 being pressed. Diagram 62 sets forth character inputs for action key 16 being pressed, while diagram 63 sets forth character inputs while action key 17 is depressed.

FIG. 5 sets forth character group diagrams 50, 51, 52 and 53 which correspond to shift state 2 or 2 locked. Thus, diagram 50 shows the character inputs in shift state 2 or 2 locked when action key 14 is pressed while diagram 51 shows character inputs in shift state 2 or 2 locked while action key 15 is pressed. Diagram 52 shows character inputs in shift state 2 or 2 locked with action key 16 while diagram 53 shows character inputs in shift state 2 or 2 locked with action key 17 being pressed.

As an assisting feature, particularly useful during the early use of the present invention, the selected keyboard diagrams (FIGS. 3, 4, 5 or 6) may be displayed on the image display unit of the host PDA or the like. Further, it may also be advantageous to visually indicated other status items (such as current shift state) using LEDs screen icons or the like.

FIG. 6 sets forth character group diagrams 70, 71, 72 and 73 which correspond to action keys 14, 15, 16, and 17 during shift state 3 or 3 locked. As can be seen in FIG. 6, the majority of keystroke designations in diagrams 70 through 73 are blank indicating that the user may selectively designate keystroke and character relationships for shift state 3 or 3 locked which meet specific needs such as Greek letters, commands or the like. This gives the present invention system substantial flexibility of use.

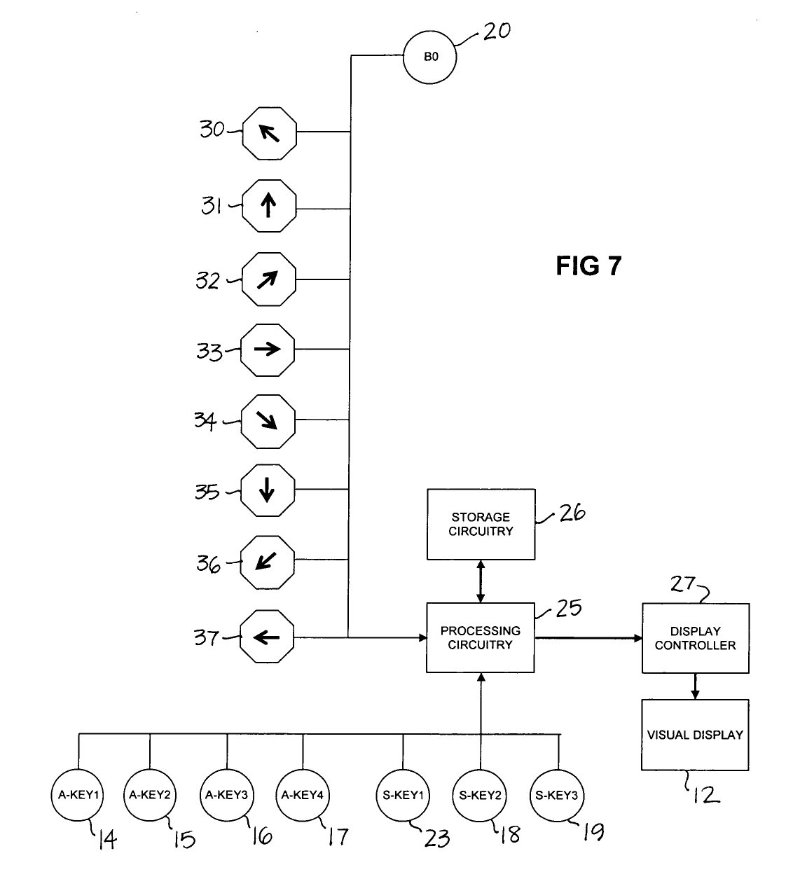

FIG. 7 sets forth a block diagram of the basic elements of the present invention text entry coding system. As mentioned above, PDA 10 (seen in FIG. 2) includes internal computer circuitry for signal processing, storage and for display control. In FIG. 7, the computer processing circuitry of the host PDA such as PDA 10 shown in FIG. 2 is represented by processing circuitry 25 which is operatively coupled to memory storage 26. Processing circuitry 25 is further coupled to a display controller 27 which in turn is operatively coupled to visual display 12. It will be recalled that visual display 12 preferably comprises a touch screen display. A plurality of inputs each corresponding to a position of joystick is illustrated by inputs 30 through 37. Thus, it will be understood that each movement to one of the eight possible positions available to the joystick results in a particular switch input to processing circuitry 25. Inputs 30 through 37 maintain their relationship to directions 30 through 37 of joystick 13 shown in FIG. 2. An additional input to processing circuitry 25 is provided by button 20 which is often referred to herein as button zero. Processing circuitry 25 is operative under the control of stored instruction within memory 26. Processing circuitry 25 includes further inputs corresponding to action keys 14 through 17 as well as shift state buttons 18, 19 and 23. Action keys 14 through 17 as well as shift keys 18, 19 and 23 comprise active inputs to processing circuitry 25 while joystick position inputs 30 through 37 and button 20 provide passive inputs. Processing circuitry 25 is operatively coupled to display controller 27 which, in accordance with conventional fabrication techniques, controls the images displayed by visual display 12.

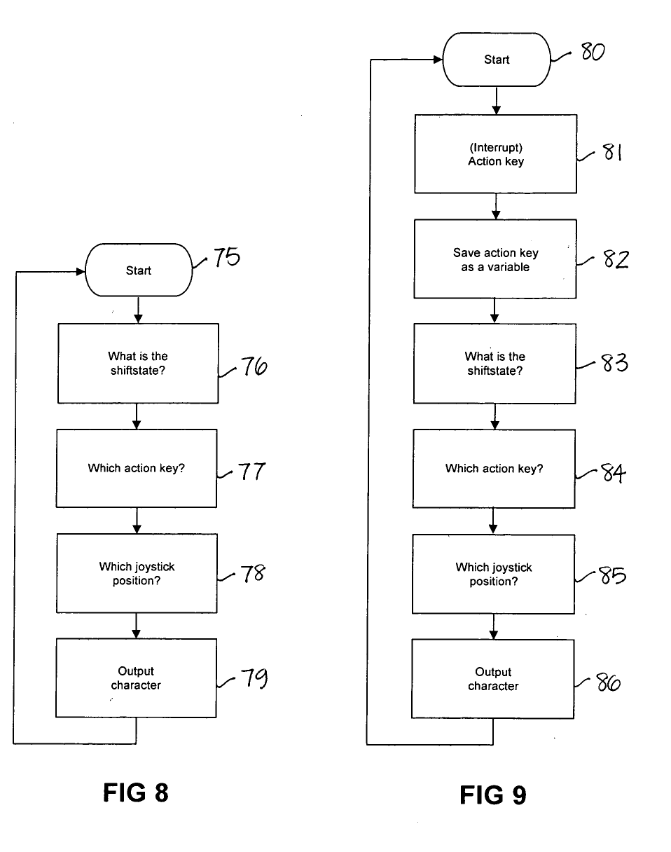

FIGS. 8, 9 and 10 set forth respective flow diagrams which depict alternate embodiments of the present invention system operation. By way of overview, it will be recalled that a particular character is selected for output of the computing system within PDA 10 in accordance with a selected shift state together with the chording or simultaneous actions of a selected action key and a selected position of the joystick controller. It will be further recalled that the shift state determines which keyboard or character set is to be selected. The keyboard or character sets for shift states 0, 1, 2 and 3 are set forth respectively in FIGS. 3, 4, 5 and 6. FIG. 3 depicts the keyboard or character set corresponding to shift state 0 while FIG. 4 depicts the keyboard or character set corresponding to shift states 1 or 1 locked. Similarly, FIG. 5 depicts the keyboard or character set corresponding to shift states 2 or 2 locked. While FIG. 6 depicts the keyboard or character set corresponding to shift states 3 or 3 locked. Within each of the keyboards or character sets, set forth for the various shift states and depicted in FIG. 3 through 6, four character groups are defined. Once a shift state is set and a keyboard or character set is determined, the desired character is selected by chording or simultaneously manipulating an action key and a joystick position. The action key selects a particular character group within the shift state determined keyboard or character set while the joystick position selects a particular character within the action key selected character group. Thus, FIGS. 8, 9 and 10 set forth simplified flow diagrams which in essence depict alternative sequences of software operation which may be carried forward to implement the above-described system.

More specifically, FIG. 8 sets forth a flow diagram of system operation which commences at a start step 75. At start step 75, the shift state of the system is initially set to a default condition of shift state 0. Thereafter, at step 76 a determination is made as to the shift state selection inputted by the user. This shift state selection determines which keyboard or character group is to be used. Thereafter, at step 77, the system determines which action key has been activated by the user. The action key activated tells the system which character group within the selected keyboard or character set is to be used. Thereafter, at step 78 the system determines which joystick position has been chorded with the selected action key to determine which character is to be outputted by the software system. Thus, the to-be-outputted character is fully determined by the established shift state together with the chorded action key and joystick position. At step 79, the selected character is outputted by the software system and the system returns to start step 75.

FIG. 9 sets forth a flow diagram of a somewhat different sequence of steps to perform the operation of the present invention system. Beginning at a start step 80 in which shift state is set to the default condition of shift state 0, the system moves to an interrupt step at step 81 produced as the result of an action key activation. Thereafter, the system moves to a step 82 which saves the activated action key as a variable. Next, the system moves to a step 83 in which a determination is made as to the shift state selected. It will be recalled that the shift state selected determines which keyboard or character set is to be utilized. Next, the system moves to a step 84 in which a determination is made as to which action key has been activated. It will be recalled that the action key selected determines which character group within a selected keyboard or character set is to be used. Finally, the system moves to a step 85 in which the joystick position is determined. It will be recalled that the joystick position determines which character within a selected character group is to be outputted. At step 86, the selected character is outputted by the software system and the system returns to start step 80.

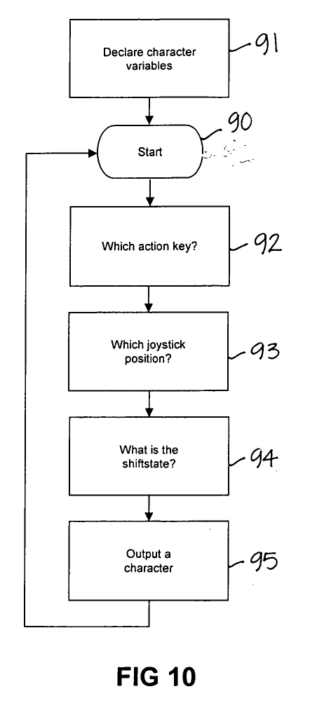

FIG. 10 sets forth a simplified flow diagram of operation of a further alternate embodiment of the present invention system. Beginning at a start step 90, the system operates at step 91 to declare four character shift variables and further includes setting the shift state to a shift state 0 default condition. Thereafter, at step 92 a determination is made as to which action key has been activated. Following step 92, the system moves to step 93 and determines which joystick position has been selected. At step 94, a determination is made as to which shift state has been established. In the system of FIG. 10, values are established for each of the four character shift variables in response to the action key and joystick position determined in steps 92 and 93. This results in the establishing of four output characters which are selected in response to the shift state determined at step 94. At step 95, the selected one of the characters corresponding to the four character shift variables is outputted and the system returns to start step 90.

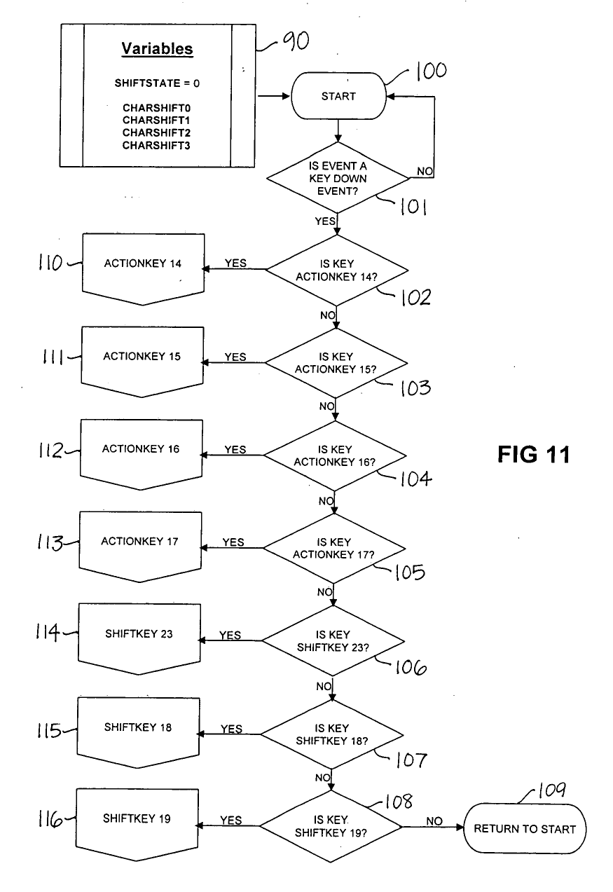

It will be apparent to those skilled in the art that FIGS. 8, 9 and 10 each set forth overview or simplified flow diagrams which generally depict alternative software programming approaching to implementing the present invention system. To provide more specific description of the present invention system, a more detailed flow diagram set is set forth in FIGS. 11 through 19. It will be noted that for purposes of illustration, the detailed flow diagrams set forth in FIGS. 11 through 19 correspond closely to the overview diagram set forth in FIG. 10. It will be remembered however that corresponding software programs operating in accordance with the overview diagrams of FIGS. 8 and 9 are equally well applicable to the present invention system.

In the examination of FIGS. 11 through 19 which set forth the operational flow diagrams of the present invention text entry coding system, it will be apparent to those skilled in the art that various types of software code may be written to implement the operation of the present invention system set forth therein. Thus, the descriptions of FIGS. 11 through 19 which follow will be understood to be descriptive of the operation of the present invention text entry coding system which may be implemented by a number of particular software code systems.

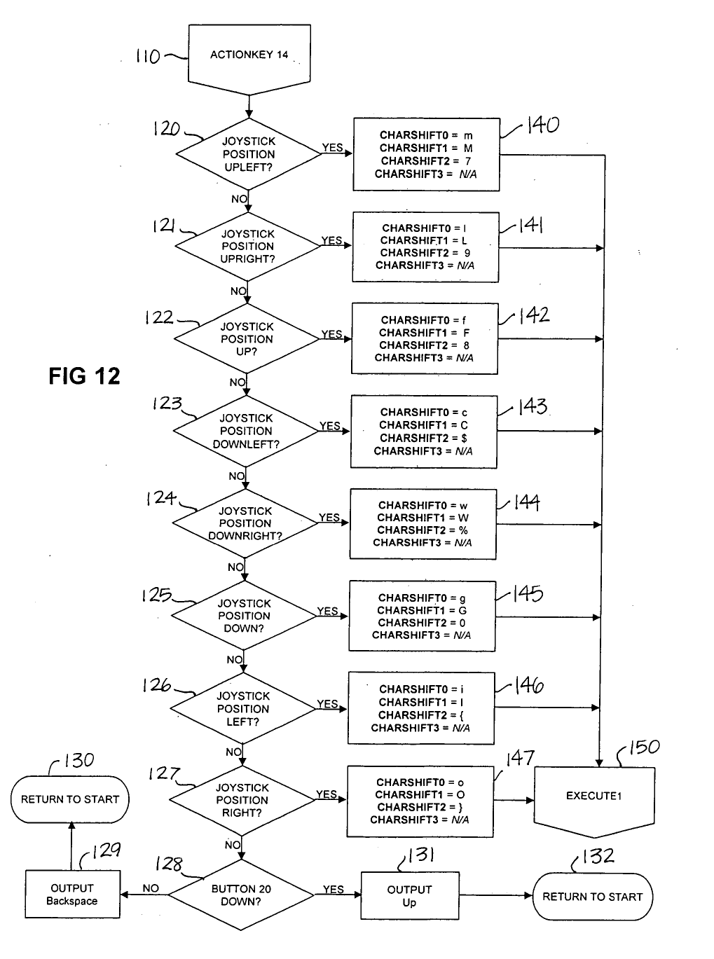

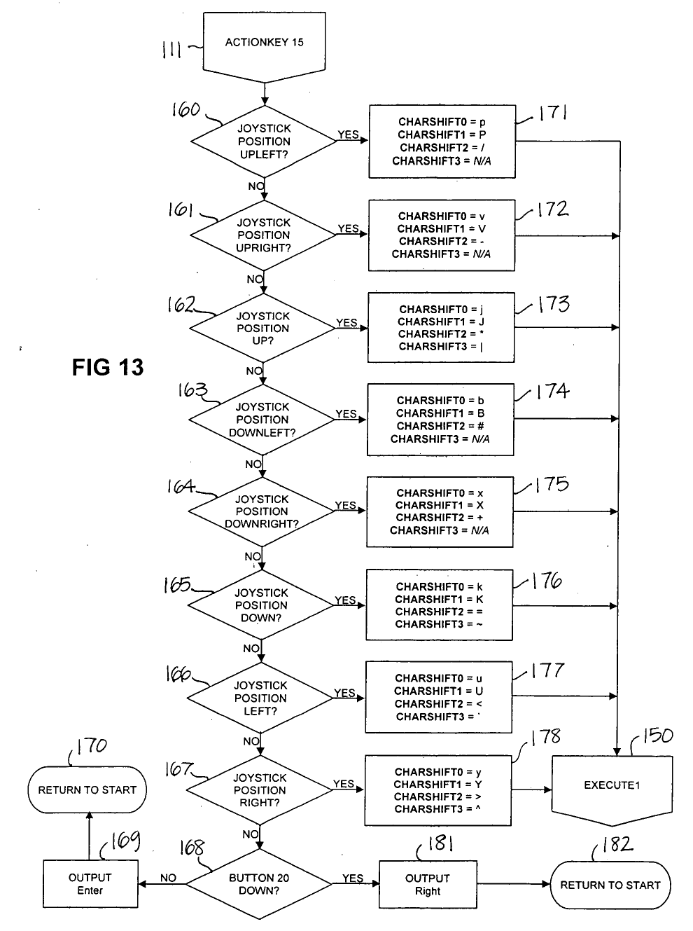

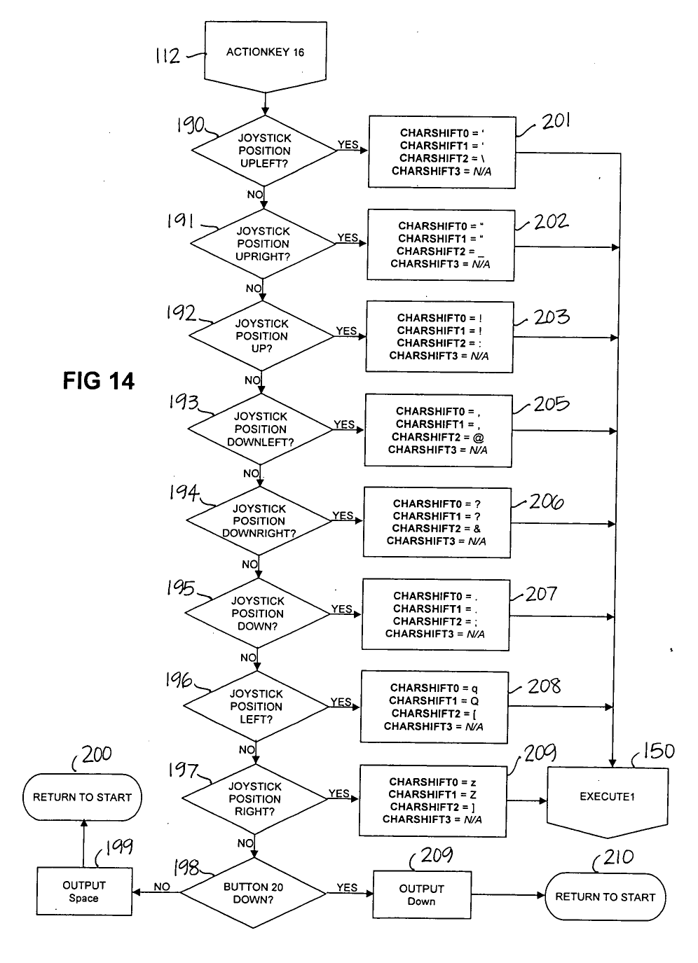

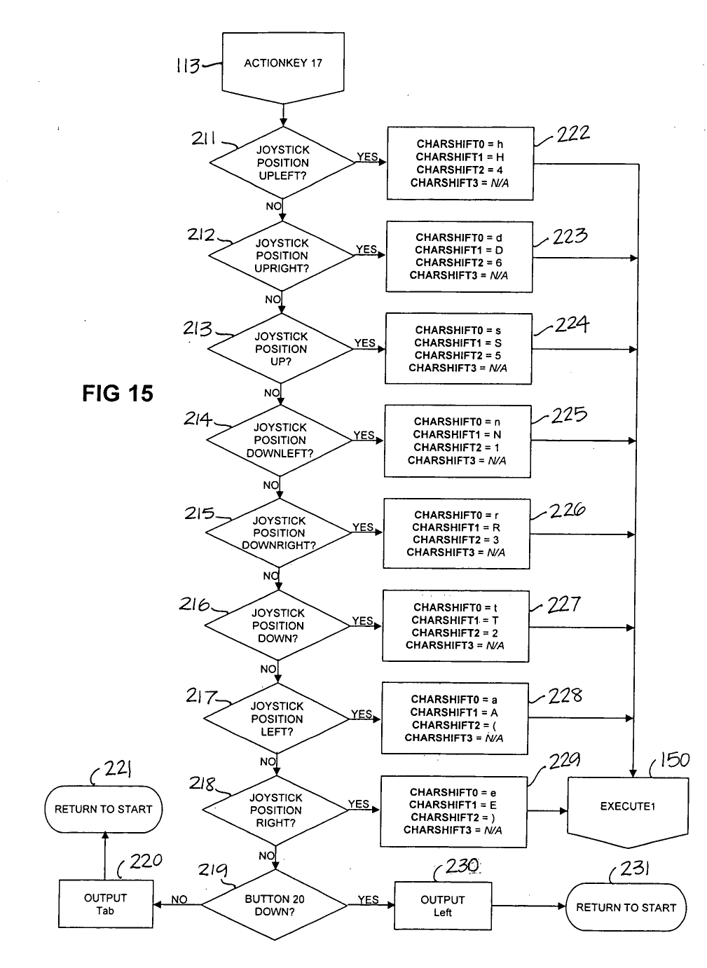

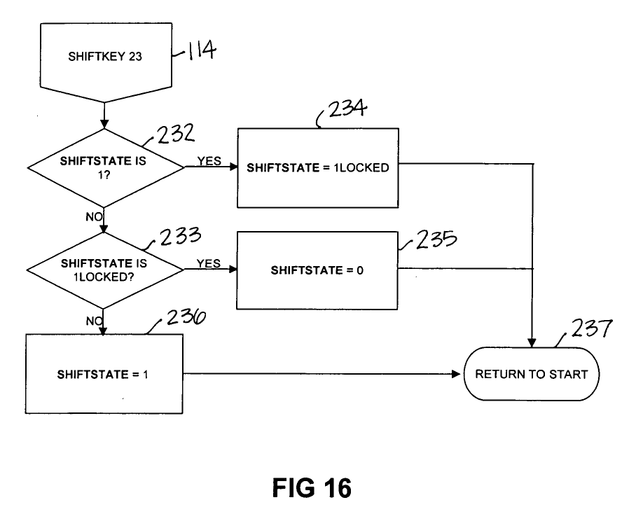

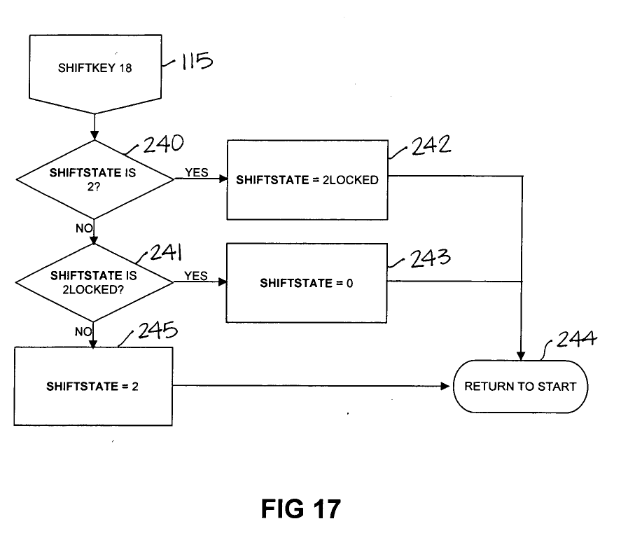

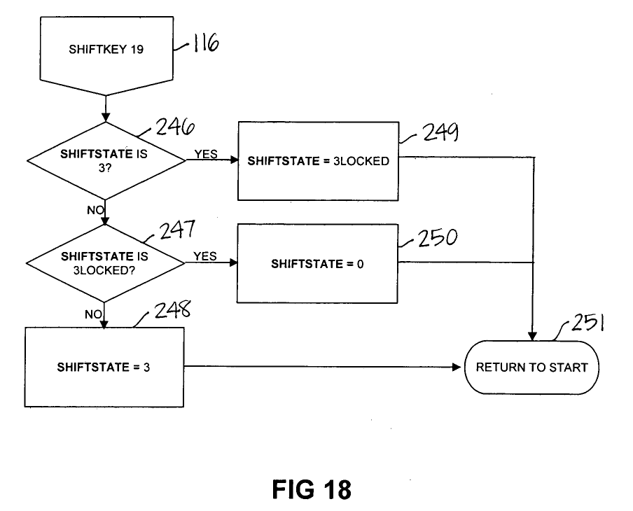

More specifically, FIG. 11 sets forth the initial operation of the present invention text entry coding system beginning at a start condition 100. Start condition 100 is determined by declaring four character shift system variables 90 and setting the shift state as shift state 0. Following start condition 100, the system determines at step 101 whether the next event is a keydown event. This determination is required due to the tendency of systems operative in response to button pressing and release to interpret a keydown or keyup as an event as well as other system events that are not key related. The present invention system is intended to respond to the pressing of a key (a keydown event). If it is determined that the event is not a keydown event, the system returns to step 100. If however a keydown event is detected, the system moves to step 102 in which a determination is made as to whether action key 14 has been pressed. If action key 14 has been pressed, the system moves to action key 14 state 110 set forth in FIG. 12. In the event at step 102 a determination is made that action key 14 is not pressed, the system then determines at step 103 whether action key 15 has been pressed. If action key 15 is determined to have been pressed at step 103, the system moves to action key state 111 shown in FIG. 13. If a determination is made at step 103 that action key 15 has not been pressed, the system moves to step 104 in which a determination is made as to whether action key 16 has been pressed. If action key 16 has been pressed, the system moves to action key step 112 shown in FIG. 14. In the event a determination is made at step 104 that action key 16 has not been pressed, the system moves to step 105 and determines whether action key 17 has been pressed. If action key 17 has been pressed, the system moves to action key state 113 shown in FIG. 15. If however at step 105 it is determined that action key 17 has not been pressed, the system moves to step 106 to determine whether shift key 23 has been pressed. If shift key 23 has been pressed, the system moves to shift key 23 step 114 shown in FIG. 16. If a determination is made at step 106 that shift key 23 has not been pressed, the system moves to step 107 and determines whether shift key 18 has been pressed. If shift key 18 has been pressed, the system moves to shift key 18 step 115 shown in FIG. 17. If however a determination is made at step 107 that shift key 18 has not been pressed, the system moves to step 108 and determines whether shift key 19 has been pressed. If shift key 19 has been pressed, the system moves to shift key 19 state 116 shown in FIG. 18. If however it is determined at step 108 that shift key 19 has not been pressed, the system executes a return to start 109 and returns to start position 100. Thereafter, the cycle continues until a determination is made in any of steps 102 through 108 that a keydown stroke for either an action key or shift key has been initiated.

FIG. 12 sets forth the flow diagram of the present invention system following the detection of a downstroke of action key 14. Action key 14 operational response begins at step 110 and thereafter moves to step 120 to determine if the joystick has moved to the upper left position. If the joystick has moved to the upper left position, the system moves to step 140 and sets the variables charshift 0, charshift 1, charshift 2, charshift 3 appropriately depending on the position of joystick and the action key pressed. If however a determination is made at step 120 that the joystick has not moved to the upper left position, the system moves to step 121 to determine whether the joystick has been moved to the upright position. If the joystick has moved to the upright position, the system moves to step 141 and appropriately sets the variables charshift 0-3. If however a determination is made that the joystick has not moved to the upright position, the system moves to step 122 to determine whether the joystick has been moved to the straight up position. If the joystick has been moved to the straight up position, the system moves to step 142 and sets the variables appropriately. If however a determination is made that the joystick is not moved to straight up position, the system moves to step 123 to determine whether the joystick has been moved to the down left position. If the joystick has been moved to the down left position, the system moves to step 143 and sets the variables appropriately. If however the joystick has not moved to the down left position, the system moves to step 124 and determines whether the joystick position has been moved to the downward right position. If the joystick has been moved to the downward right position, the system moves to step 144 and sets the variable appropriately. If however the joystick has not moved to the downward right position, the system moves to step 125 and determines whether the joystick has been moved to the straight down position. If the joystick has been moved to the straight down position, the system moves to step 145 and sets the variables appropriately. If however the joystick has not been moved to the straight down position, the system moves to step 126 and determines whether the joystick has been moved to the left position. If the joystick has been moved to the left position, the system moves to step 146 and sets the variables appropriately. If however the joystick has not been moved to the left position, the system moves to step 127 and determines whether the joystick has been moved to the right position. If the joystick has been moved to the right position, the system moves to step 147 and sets the variables appropriately.

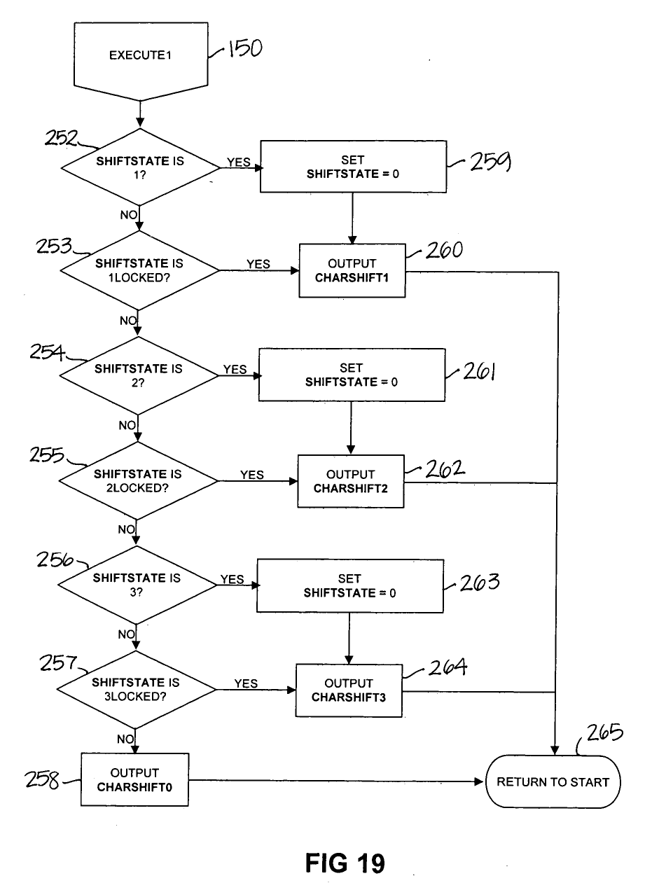

For each of the variable setting states 140 through 147 the system moves to an execute step 150 and thereafter proceeds as set forth in FIG. 19. If however a determination is made at step 127 that the joystick has not been moved to the right, the system moves to a step 128 and determines whether button 20 has been pressed. In the event button 20 has not been pressed, the system moves to step 129 and outputs a backspace signal and thereafter executes a return to start at step 130. Return to start step 130 causes the system to return to start step 100 shown in FIG. 11.

If however a determination is made at step 128 that button 20 has been pressed, the system moves to step 131 and outputs an “up” command or code or character after which the system executes a return to start step 132. Step 132 causes the system to return to start step 100 in FIG. 11.

FIG. 13 sets forth a flow diagram of the operation of the present invention system in response to the determination that action key 15 has been pressed, comparisons of FIGS. 12 and 13 will show that the structure of the flow diagram in FIG. 13 is substantially identical to the structure of the flow diagram of FIG. 12. That is to say, the operation of the present invention system in response to determination that action key 15 has been pressed is carried forward in a fashion similar to the systems response to the pressing of action key 14.

Thus, in the operation shown in FIG. 13, the system moves in a similar fashion to that described in FIG. 12 following step 111 the system moves through successive determinations of joystick position in steps 160 through 167. By way of further similarity, the system in response to an affirmative determination at any of steps 160 through 167 moves to the corresponding character output step found in step 171 through 178. In further similarity to the operation shown in FIG. 12, following each variables setting step, the system moves to execute step 150 set forth in FIG. 19.

In response to a determination at step 167 that in essence no joystick position has been initiated, the system moves to a step 168 determining whether button 20 has been pressed and if not moves to step 169 at which an output corresponding to carriage return or enter is produced. Thereafter, at a return to start step 170, the system returns to start step 100 shown in FIG. 11. If however button 20 is not found to be depressed at step 168, the system moves to step 181 in which an output corresponding to a “right” command or code or character is produced. Thereafter, the system moves to a return to start step 182 which causes the system to return to start step 100 shown in FIG. 11.

FIG. 14 sets forth the operational flow diagram of the present invention system in response to a determination that action key 16 has been pressed. Once again, the operation of the present invention system set forth in FIG. 14 is substantially identical in structure to the operation set forth in FIG. 12 in response to pressing of action key 14. Thus, with action key 16 pressed, the system moves from step 112 to a sequence of joystick position determining steps 190 through 197. In each of steps 190 through 197, a determination that the particular joystick position movement has occurred, the system moves to the corresponding one of variables setting steps 201 through 208. After the appropriate variables setting having been produced at steps 201 through 208, the system moves to step 150 for execution carried forward in FIG. 19. In the event a determination is made in steps 190 through 197 that the joystick position has not been moved, the system moves to a step 198 for a determination as to whether button 20 has been pressed. If not, the system moves to step 199 and outputs a space character after which a return to start step 200 is carried forward returning the system to start step 100 shown in FIG. 11. If however button 20 has been pressed, the system moves to step 209 and outputs a “down” character, command or code and thereafter moves to step 210 for a return to start step 100 shown in FIG. 11.

FIG. 15 sets forth the operational flow diagram of the present invention system in response to pressing action key 17. Once again, the operation of system shown in FIG. 15 is substantially identical to the operation of the system shown in FIG. 12. Accordingly, in response to the pressing of action key 17, the system moves through a sequence of steps 211 through 218 in which the position of the joystick is detected. From each of steps 211 through 218 a determination of a particular joystick position causes the system to move to a corresponding variables 222 through 229. Following the appropriate one of steps 222 through 229 the system moves to execute step 150 shown in FIG. 19.

In the event a determination is made at steps 211 through 218 that no joystick position input has been initiated, the system moves to a determination at step 219 as to whether button 20 has been pressed. In the event button 20 has not been pressed, the system moves to step 220 producing a tab character output and thereafter returns to start 100 via step 221. If however button 20 has been pressed, the system moves to step 230 and outputs a left command, character or code moving to step 231 and returning to start 100 shown in FIG. 11.

FIG. 16 sets forth the operation of the present invention system following a determination in step 106 that shift key 23 has been pressed (see FIG. 11). Thus, beginning at step 114, the system moves to steps 232 and 233 for successive determinations of whether the shift state is one or is state one locked. In the event the system is at shift state one, the system moves to step 234 and changes the system to shift state one locked. Thereafter, the system returns to start at step 237. In the event the shift state is shift state one locked, the system moves to step 235 and changes the shift state to zero thereafter moving to step 237. In the event a determination is made at steps 232 and 233 that neither shift state one or shift state one locked is present, the system moves to step 236 setting the shift state equal to one and thereafter returning to start via step 237.

FIG. 17 sets forth the operation of the present invention system in response to a determination at step 107 in FIG. 11 that shift key 18 has been pressed. It will be apparent by comparing FIG. 17 to FIG. 16 that the response of the present invention system is structurally the same for a determination of shift key 18 as the response shown in FIG. 16 for shift key 23. More specifically, following step 115 the system moves to successive steps 240 and 241 to determine whether the shift state is two or the shift state is two locked respectively. In the event neither shift state two nor shift state two locked is found, the system moves to step 245 setting the shift state equal to two and returning to start step 100 via step 244. In the event however shift state two is determined, the system moves to step 242 setting the shift state to two locked and thereafter returning to start through step 244. If shift state two locked is determined, the system moves to step 243 setting the shift state to zero and returning to start through step 244.

FIG. 18 sets forth the system operation in response to a determination at step 108 that shift key 19 has been pressed. It will be apparent that the operation set forth in FIG. 18 is substantially the same as is set forth in FIG. 16. Accordingly, following step 116, the system determines at steps 246 and 247 whether shift state three or shift state three locked is present. In the event neither is present, the system moves to step 248 setting the shift state to three and returning to start via step 251. If, however, the shift state is three, the system moves to step 249 setting the shift state equal to shift state three locked and returning to start through step 251. If shift state three locked is detected, the system moves to step 250 setting the shift state to zero and returning to start via step 251.

FIG. 19 sets forth a flow diagram of the execute portion of the present invention system beginning at execute step 150. Following step 150 in which the system enters the execute portion of operation, the system moves to a succession of steps 252 through 257 in which determinations are made as to the shift state or shift state locked condition of the system. Thus, in the event a shift state one is determined at step 252, the system moves to step 259 setting the shift state to zero and thereafter moving to output the character that was designated to variable charshift 1 at step 260. Similarly, in the event a shift state two is determined at step 254, the system moves to step 261 setting the shift state to zero and thereafter moving to a output the character that was designated to variable charshift 2 step 262. Similarly, in the event shift state three is detected at step 256, the system moves to step 263 setting the shift state to zero and thereafter moving to output the character that was designated to variable charshift 3 at step 264.

Similarly, in the event a shift state one locked is determined at step 253, the system moves directly to step 260. In the event a shift state two locked is found at step 255, the system moves directly to step 262. Finally, in the event a shift state three locked is found at step 257, the system moves directly to step 264. In the event neither shift states one through three or locked shift states one through three is found at steps 252 through 257, the system moves to step 258 and outputs the character that was designated to variable charshift 0.

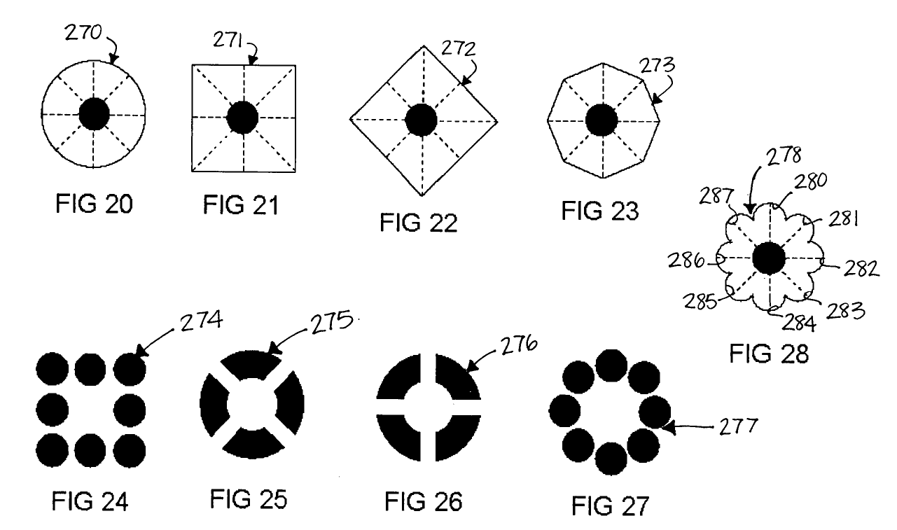

FIGS. 20 through 23 set forth alternative joystick input devices for use in accordance with the present invention which are generally referenced by numerals 270, 271, 272 and 273 respectively. Input devices 270 through 273 are different shaped devices having variously shaped recesses all of which provide a plurality of at least eight positional inputs.

FIGS. 24 and 27 set forth square and circular arrangements of eight buttons each generally referenced by numerals 274 and 277 respectively which also may be utilized in the present invention system in place of joystick 13 shown in FIG. 1.

FIGS. 25 and 26 set forth alternative arrangements of buttons which may also be used in providing the eight condition inputs of joystick 13 (seen in FIG. 1). In devices 275 and 276, the user may input directional inputs by simply pressing on either on the center portion of a chosen button or pressing at the junction of two buttons causing them to simultaneously actuate. In this manner, eight positional inputs are provided.

FIG. 28 sets forth a further alternative joystick variation in which a multiple-position defining recess 278 establishes a plurality of separated joystick positions 280 through 287.

While particular embodiments of the invention have been shown and described, it will be obvious to those skilled in the art that changes and modifications may be made without departing from the invention in its broader aspects. Therefore, the aim in the appended claims is to cover all such changes and modifications as fall within the true spirit and scope of the invention. For example, the character layout for any given application may be selected based on frequency of character use. Also, the present invention system may be used for other systems such as gaming utilizing a controller with joystick and buttons. Finally, additional shift states may be used beyond the number shown in the preferred embodiments herein.

That which is claimed is:

1. A keystroke chording system operative within a computing system comprising:
a multi-position control;
a plurality of discreet input buttons; and
means operative within said computing system for outputting a character selected by chording said multi-position control and a selected one of said input buttons wherein each combination of joystick position input and input button input produces a character output to the computing system for display and text entry.

2. The keystroke chording system set forth in claim 1 further including at least one shift key input for establishing a selected shift state whereby a character output to the computing system for displaying and text entry is further determined by the shift state established by said shift key input.

3. The keystroke chording system set forth in claim 2 wherein said plurality of discreet input buttons comprise four buttons and said multiposition control is a joystick control.

4. The keystroke chording system set forth in claim 3 wherein said at least one shift key input includes a button and means for incrementing said shift state in response to said button.

5. The keystroke chording system set forth in claim 4 wherein said at least one shift key includes three buttons defining three shift states entered by pressing a selected one of said shift key buttons and a fourth shift state entered when none of said shift key buttons is pressed.

6. The keystroke chording system set forth in claim 3 wherein said computing system is utilized within a small handheld unit having a front face supporting a display screen, said joystick control and said plurality of buttons, said housing further defining an outer edge.

7. The keystroke chording system set forth in claim 6 wherein said three shift key buttons include two buttons supported on said outer edge.

8. The keystroke chording system set forth in claim 7 wherein said three shift key buttons include a button actuated by said joystick control in a center-position press-down movement.

9. The keystroke chording system set forth in claim 1 wherein said multi-position control is a joystick control.

10. The keystroke chording system set forth in claim 8 wherein said plurality of discreet input buttons comprise four buttons.

11. For use in a handheld computing device supported within a housing having a front face and outer edge, a display screen on said front face, a pair of buttons on said outer edge, a multi-position joystick control supported on said front face and a plurality of discreet input buttons supported on said front face, a keystroke chording system comprising:
first means operative within said computing device outputting a character selected in response to a selected position of said joystick control in combination with a selected one of said discreet input buttons;
second means within said computing device responsive to the actuation of said pair of buttons to establish a first shift state when neither button is pressed, a second shift state when one of said buttons is pressed and a third shift state when the other of said buttons is pressed; and
third means within said computing device responsive to said shift state for establishing first, second and third character sets from which said first means select characters.

12. The keystroke chording system set forth in claim 11 wherein said first, second and third means are operative in a software program.

13. The keystroke chording system set forth in claim 12 further including a third button operative to establish a fourth shift state when pressed.

14. The keystroke chording system set forth in claim 13 wherein said third button is actuated by said joystick controller in its center position.
